(19) United States
(12) Patent Application Publication
(10) Pub. No.: US 2026/0361266 A1
(43) Pub. Date: Nov. 12, 2026

(54) ENERGY STORAGE SYSTEM

(71) Applicant: AED ENERGY LTD, London (GB)

(72) Inventor: Oliver WEBER, Oxford (GB)

(73) Assignee: AED ENERGY LTD, London (GB)

(21) Appl. No.: 19/474,866

(22) PCT Filed: Apr. 12, 2024
(86) PCT No.: PCT/EP2024/060091

§ 371 Date: Oct. 13, 2025

(30) Foreign Application Priority Data
Apr. 12, 2023 (GB) 2305378.8

(51) Int. Cl. H02S 40/22; H02S 40/38; H02S 40/44

(52) U.S. Cl. CPC H02S 40/22; H02S 40/38; H02S 40/44

(57) ABSTRACT

There is provided a thermal energy storage apparatus including a thermal energy storage medium, a photovoltaic device, and a bidirectional waveguide, wherein the bidirectional optical waveguide is configured to guide radiation from the thermal energy storage medium to the photovoltaic device and also to guide radiation which passes through the photovoltaic device back to the thermal storage medium from the photovoltaic device. Also described are energy storage facility, an energy grid, a method of improving the efficiency of an energy grid or energy storage facility, and the use of such thermal energy storage apparatus or energy storage facility or energy grid in a method of storing and releasing energy or in a thermal energy storage apparatus, energy storage facility or energy grid.

### FIELD OF INVENTION

The present disclosure relates to a thermal energy storage apparatus, an energy storage facility, a method of improving the efficiency of an energy grid, and the use of a thermal energy storage apparatus, energy storage facility, or energy grid in a method of storing and releasing energy, and the use of a method of improving the efficiency of an energy grid. In particular, the present disclosure relates to a thermal energy storage and thermophotovoltaic radiant energy conversion device using waveguide materials/structures to enable power discharge from a deeper volume of the thermal storage, improved thermal management of the photovoltaic device remote from the high temperature source, minimisation of thermal losses from optical transmission, and optimisation of energy and power density. The present disclosure has particular, but not exclusive application, to long duration storage of energy as heat in a thermal mass as well as conversion of waste heat to electrical power. The thermal energy storage apparatus may also be referred to as a thermal battery.

### BACKGROUND

In recent years there has been renewed interest in thermophotovoltaic systems that convert the radiant energy emitted from heat sources, which can be at temperatures up to the order of 2000 °C, to electricity using photovoltaic cells.

These devices are of interest for storage of renewable energy sources at times of excess generation, provision of combined heat and electric power, conversion of waste heat sources to electricity and extremely lightweight solid-state power converters of combustion fuels to electricity.

Scalable solutions are required to take low-carbon, intermittent generation of electricity from renewable sources like wind and solar and turn it into on-demand power and heat. Buildout rates for renewable generation can be bottlenecked by transmission and existing renewable generation is regularly curtailed due to supply and demand mismatching. Energy storage serves multiple roles as an enabler for flexibility, resilience of energy supply, maximising renewables fraction on the grid and enabling the provision of on-demand low carbon electricity.

Commercial applications of thermophotovoltaics have historically been limited by system conversion efficiency and complex design management for balancing incident photon power density and heat load onto the photovoltaic (PV) receiver. However, 41% heat to electric conversion efficiencies have recently been demonstrated using a blackbody emissive source and multijunction PV cell as a band-edge spectral filter, with an efficient back reflector for efficient recycling of sub-band gap infra-red photons. This puts the technology into the same efficiency conversion bracket as steam turbines, while being all-solid-state and lightweight.

In order to try to maximise the efficiency of existing thermophotovoltaic systems, reflective surfaces have been provided on photovoltaic cells such that radiation which is not absorbed by the PV cell, which is referred to as out-of-band radiation, is reflected back to the emitter. However, there are significant losses at the interface of the mirror and the PV cell. In addition, the thermal radiation is only emitted by the immediate surface portion of the emitter and so it is inefficient for discharging the entire thermal capacity of the thermal mass. For solid sensible heat materials this also results in large thermal gradients, which are undesirable.

Existing thermal batteries aim to increase output power density by moving the thermal mass, such as in pumped systems using molten salts or other heat transfer fluids. This requires additional pumping means, such as mechanical pumps, to cause the thermal mass to move, which themselves use electricity and are subject to breakdown. Other thermal battery systems increase the geometric view factor to the receiver by selectively removing parts of the thermal mass, thereby reducing volumetric storage capacity.

It is an object of the present invention to obviate or mitigate one or more disadvantages of the current systems, whether identified herein or otherwise.

### SUMMARY OF THE INVENTION

According to a first aspect of the present disclosure, there is provided a thermal energy storage apparatus including a thermal energy storage medium, a monofacial or bifacial photovoltaic device, and a bidirectional waveguide, wherein the bidirectional optical waveguide is configured to guide radiation from the thermal energy storage medium to one or both sides of the photovoltaic device and also to guide radiation which is reflected back or passes through the photovoltaic device back to the thermal storage medium.

The bidirectional waveguide may concentrate the radiation. The bidirectional waveguide may collimate the radiation. The bidirectional waveguide may concentrate and collimate the radiation. By concentrating and/or collimating the radiation, the efficiency of the apparatus can be fine-tuned and optimised. This may be due to the ability to increase the power density incident on a PV cell.

The radiation may include visible, near infra-red, and/or infra-red radiation. The photovoltaic device can be configured to convert such radiation into electrical power.

The bidirectional waveguide may be configured to guide radiation back to the thermal storage medium from one or both sides of the photovoltaic device.

It is desirable to maximise the efficiency of thermal energy storage apparatuses. By providing a bidirectional waveguide which illuminates both sides of a bifacial photovoltaic device, it is possible to double the incident power density on the PV device and also avoid the losses associated with back surface reflection. In addition, by configuring the system to guide radiation which is not absorbed by the PV device back into the thermal storage medium via the bidirectional waveguide, it is possible to enable power discharge and recharge from a greater proportion of the thermal storage media onto a smaller photovoltaic device area. In this way, optical transmission losses that originate within the confines of the apparatus, such as from an insulated energy storage section, do not reduce overall system efficiency. As such, energy capacity is at least partially decoupled from power density incident on the cell since a plurality of optical waveguides can be provided which are able to guide and optionally concentrate thermal radiation energy from more of the thermal energy storage medium. No moving thermal energy storage medium is used and so the system is static, which reduces the likelihood of mechanical breakdown and also reduces maintenance costs. This not only allows for a greater proportion of the stored thermal energy to be used, this allows for the energy to be discharged and charged more quickly, and also improves the thermal management of the thermal storage medium by reducing thermal gradients in the thermal energy storage medium. The present invention provides improvements in power density, volumetric discharge of radiant energy from a thermal storage medium, and thermal management of a thermophotovoltaic cell receiver. System efficiency losses are minimised by configuring the apparatus such that light not absorbed by the thermophotovoltaic device is recycled back to the same thermal energy storage device or another thermal storage device or medium. The present disclosure improves heat transfer by including elements within the thermal energy storage medium to increase thermal conductivity and/or radiative heat transfer, which may be reflective non-imaging optical elements such as parabolic or ellipsoidal mirrors, imaging optics or total-internal-reflection elements such as refractory optical emitter-waveguides. Such optical elements may be used singly or in combination. Such refractory optical fibres or bundles of such fibres maximise the surface area of the emitter, and concentrate radiant emission to a photovoltaic receiver, where it is converted into electricity. This transmission by the optical waveguides may reduce the thermal load relative to a photovoltaic cell in proximity to the hot source by means of spectrally selective coatings. Volumetric discharge from the thermal energy storage medium results in fewer thermal gradients and resultant material stress and fatigue. It will be appreciated that bidirectional waveguide/waveguiding in the current context refers to optical elements configured alone or in combination to guide radiation in the visible and infra-red spectrum both to and from a photovoltaic device. Such optical waveguides may be lenses, non-imaging optical elements like parabolic mirrors, or utilise total internal reflection such as in optical fibres. The optical waveguides may be configured alone or in combination to collimate, concentrate and/or directionally guide radiation originating from thermally emissive surfaces. It will be appreciated that a bidirectional waveguide is any device which is able to guide electromagnetic radiation, particularly visible, near-IR and IR light, from one location to another. As such a bidirectional waveguide may guide the light via optical elements such as lenses, reflectors (mirrors), or via total internal reflection.

The thermal energy storage medium may include a sensible heat storage medium, a latent heat storage medium, or a combination thereof. The thermal energy storage medium may be a refractory blackbody absorber in thermal contact with a suitable heat source. Any heat source described herein is a suitable heat source. A sensible heat storage medium does not undergo a phase change and absorbs or releases thermal energy by changes in temperature, but not phase. A latent heat storage medium relies on a phase transition to absorb or release thermal energy. The terms heat and thermal energy are used interchangeably.

The apparatus may include a heat storage medium directly adjacent the bidirectional optical waveguide. By directly adjacent, this include the case where the heat storage medium is in direct physical contact with the optical waveguide. This also include the case where the heat storage medium is in thermal contact with the optical waveguide, but not necessarily in direct physical contact. There may be a gap between the heat storage medium and the optical waveguide. Such a gap may be a vacuum or filled with a gas. This is the case for the case where the thermal energy storage medium is a latent heat storage medium or a sensible heat storage medium. It will be appreciated that an optical waveguide may include thermoluminescent emitters as dopant or in a sheath around a core of the optical waveguide.

The latent heat storage medium may be provided between the sensible heat storage medium and the bidirectional optical waveguide. By proximity of the bidirectional optical waveguide with latent heat storage medium, the temperature of the waveguide can be regulated. Such temperature may be close to the melting point of this storage medium. By regulating the temperature of the waveguide, it can be ensured that the waveguide is exposed to temperatures which do not exceed the maximum operating temperature for the waveguide. Again, the latent heat storage medium may be indirect physical contact with the waveguide or may be spaced apart. Since the latent heat storage medium is configured to emit radiation from high emissivity surfaces, which is then conducted by the waveguide, there is preferably nothing which significantly reduces such heat transfer between the storage medium and the waveguide. The presence of a gas would not significantly reduce such transfer.

The thermal energy storage medium may be contained within an insulated container. Since the thermal storage medium is at a temperature considerably higher than ambient temperature, energy can be lost to the environment. As such, it is desirable to contain the thermal energy storage medium within a container that is insulated. For example, the insulation may have a thermal conductivity of less than 0.2 W m-1 K-1 at 25 °C. For example, the insulation may comprise alumino-silicate refractory ceramic fibres, which are stable at the operating temperature of the thermal energy system. It will be appreciated that other insulation materials with a thermal conductivity of less than 0.2 W m-1 K-1 at 25 °C and which are stable at the operating temperature of the thermal energy system may also be used.

The PV device is preferably located outside of the insulated container. This may be the case when the PV device is not extracting power. The PV device loses efficiency with increasing temperature and will suffer damage or destruction should its temperature get too high. Since the thermal energy storage medium is generally held at a temperature much higher than would be tolerated by a PV device, the PV device is preferably positioned separately from the thermal energy storage medium. It will be appreciated that the PV device could be positioned permanently within the thermal energy storage medium, but would require uninterrupted cooling to remain operational. The PV device may be located in a housing. The housing is preferably separate from the insulated container containing the thermal energy storage medium. The housing could be within the container containing the thermal energy storage medium. The housing may be provided with cooling, which may comprise a gas or liquid coolant flow

The thermal energy storage apparatus may include a heater. The heater provides thermal energy to the thermal energy storage medium. Any suitable heat source may be provided. For example, the heater may be an electric heater, a heat exchanger in thermal connection with a heat source, another thermal energy storage apparatus at a higher temperature, a solar collector, a fuel device, a radioisotope heat source, or a burner. The heater may be a high temperature flameless combustion chamber. The heat source may be from a waste heat source, such as an industrial process, such as in a chemical plant, factory, or foundry. The thermal energy storage apparatus can be charged using, for example, variable renewable electricity such as wind, via resistive heating elements or volumetric Joule heating of a thermal energy storage medium. The heater may be located within or in direct thermal contact with the thermal energy storage medium. The heater may be remote from the thermal energy storage medium and the thermal energy transferred by a thermal transfer fluid. As such, there may be a container, which is configured to store thermal energy therein, that is additional to any container which the thermal energy storage medium that illuminates the photovoltaic device. Since such an other container is not in direct thermal communication with the photovoltaic device, the temperature of the thermal energy storage medium may be higher that a temperature which a photovoltaic device may tolerate. Additionally or alternatively, the temperature of the other container does not need to be tightly controlled since there is no risk of damage to a sensitive PV device. The other container is preferably configured to selectively transfer the thermal energy to another container comprising the thermal energy storage as described herein. Such other container may therefore act as a reservoir for thermal energy which may be used to recharge an apparatus as described herein which converts such thermal energy to electricity. In this way, multiple containers of thermal energy storage medium may be thermally connected to an apparatus as described herein to act as reservoirs for a device which generates electricity via illumination of a PV device with radiation, such as in the form of visible, near IR, and IR light. It is therefore possible to adjust the overall capacity of a thermal battery by adding or removing containers of thermal energy storage medium. The invention is not particularly limited by how the thermal energy is passed from a reservoir to an apparatus as described herein and may, for example, be transferred by a thermal transfer fluid or along one or more waveguides as described herein.

The PV device may be in thermal communication with a cooling apparatus. The cooling apparatus is configured to maintain the PV device at or below its maximum operating temperature. The cooling apparatus is preferably configured to maintain the PV device within a predetermined temperature range. As mentioned, the PV device operates most efficiently in a given temperature range, which is generally well below the temperature of the thermal energy storage system. Even though the PV device may be positioned separate from the thermal energy storage medium, it is still exposed to thermal radiation and will heat up. Any suitable cooling apparatus may be used. A flowing coolant may be provided which keeps the PV device within the predetermined temperature range. The coolant may flow over one or more faces of the PV device. The PV device may include channels which direct coolant orthogonal to the direction of the optical path of the radiation through the PV device.

The apparatus may include at least two storage chambers containing respective thermal energy storage media and bidirectional waveguides. Optionally, the bidirectional waveguides are configured to provide radiation emitted from the thermal storage media to one or both opposing sides of the photovoltaic device from the at least two storage chambers. By providing two storage chambers including thermal energy storage media and bidirectional waveguides, it is possible to position a photovoltaic device between the chambers such that the bifacial PV device can be illuminated from each side. As mentioned, the apparatus may include at least two chambers containing respective thermal energy storage media in which the first chamber serves as a feeder to thermally charge, by means of a heat transfer fluid, the second chamber containing the photovoltaic device housing and optical elements. The first chamber may be significantly larger than the second chamber, such that the amount of energy stored may be proportionately higher. As mentioned, in this way one chamber may serve as a reservoir for thermal energy. There may be additional chambers to expand the thermal capacity of the system and/or to allow the provision of thermal energy from different sources, and/or at different temperatures.

The apparatus may further include at least one shutter or actuator configured to control the amount of radiation reaching the photovoltaic device. Optionally, the at least one shutter or actuator is a mechanical shutter or actuator. In some instances, it may be desirable to control the illumination of the PV device, such as when there are varying power output requirements. Since the PV device converts radiation into electrical power, by adjusting the amount of radiation illuminating the PV device, it is possible to control the electrical power output.

The apparatus may include collimating and/or concentrating optical elements. The concentrating optical element may be configured to concentrate radiation on the photovoltaic device. By concentrating the radiation on the photovoltaic device, it is possible to provide a higher flux of radiation on the surface of the photovoltaic device, which allows the PV device to operate optimally and generate electrical power at a higher power density. As such, it is possible to decouple power density from photovoltaic device area through optical concentration. Any optical element which is able to focus thermal radiation may be used and the present disclosure is not particularly limited to the exact optical element used. Optical concentration may be achieved by non-imaging optical elements such as reflective parabolic mirrors. Optical collimation of radiation from diffuse sources that approximate point sources such as blackbody emitters of limited finite size may be achieved with non-imaging or imaging optical elements. Optical concentration may be achieved by fusing and tapering fibre waveguides in an N-to-one fibre power combiner. Alternatively or additionally, a cylindrical lens array may be used to concentrate light from an emitter onto a slab or fibre waveguides. It will be appreciated that, as for non-concentrating optical elements, optical transmission losses confined to within the insulated section of the energy storage system do not contribute to the overall system efficiency losses, as the dissipated heat from these optical losses is retained within the thermally insulated section of the apparatus.

The bidirectional waveguide may include a plurality of individual waveguides. Optionally, the width of the waveguides fits within gridlines of metal contact electrodes of the photovoltaic device. By providing a plurality of individual waveguides, it is possible to convert a greater proportion of the thermal energy storage within the system. The plurality of waveguides are preferably distributed throughout the thermal energy storage medium to allow radiation from multiple areas of the apparatus to be guided to the photovoltaic device. The plurality of waveguides may be brought together to illuminate a photovoltaic device such that radiation from a plurality of areas of the thermal energy storage medium can be utilised. The photovoltaic device includes gridlines of metal contact electrodes, so preferably the waveguides are sized and located such that the radiation provided by the waveguides does not fall on the metal contact electrodes as it would not be used to generate electricity.

In an embodiment, the bidirectional waveguide is arranged to symmetrically illuminate both faces of the photovoltaic device. By symmetrically illuminating both faces of the PV device, both sides of the device can generate similar levels of electricity and also any radiation which passes through the device is transmitted into the opposite waveguide, where it is transferred to the storage medium in thermal connection with such waveguide. In one instance the optical elements focus light onto one face of the photovoltaic device, while radiation that passes through the device is reflected back from optimised reflectors on the back surface of the photovoltaic device.

The photovoltaic device may be freestanding. The photovoltaic device may be supported by a radiation, such as infra-red, transparent support. The photovoltaic device may be supported by the waveguide.

The bidirectional waveguide may comprise one or more of alumina, silica, and yttrium aluminium garnet (YAG). These materials are able to transmit visible and near infra-red radiation. Refractory fibres of alumina, silica, and YAG are available as optical components for lasing.

The bidirectional waveguide may include thermoluminescent emitters configured to emit predetermined wavelengths of radiation. Optionally, the thermoluminescent emitters are selected from transition metal oxides, such as cobalt oxide, rare earth oxides, such as erbium oxide, or combinations thereof. By including emitters which are configured to emit predetermined wavelengths of radiation, it is possible to improve efficiency as the PV device can be selected to efficiently convert such predetermined wavelengths to electrical power. In an embodiment, there may be provided coupling of radiation from a blackbody source, such as the thermal energy storage medium, can be provided to a waveguide, resulting in broadband emission superimposed on narrowband emission of selective thermoluminescent emitters. The thermoluminescent emitters may be provided as dopants to the waveguide itself or as a thin layer of emitter material between a fibre core and a transparent cladding having a lower refractive index than the fibre core. In this way, the thermal storage medium does not necessarily need to be a good emitter as thermoluminescent emitters can be provided which are able to act as better emitters.

The thermal energy storage medium may include one or more of silicon, iron, aluminium, calcium, manganese, sodium, potassium, lithium, and magnesium. Preferably such thermal energy storage medium is latent heat storage medium. It will be appreciated that such elements will be in the form of compounds rather than in elemental form. The sensible heat storage medium may be composed of compound metal oxides of the above-listed elements, carbon, or silicon carbide.

The photovoltaic device may be separated from the thermal energy storage medium. This may be achieved by a transmissive material, a vacuum, or both. As described above, the PV device operates best in a given temperature range. Since the thermal energy storage medium is likely at a temperature above this range, the PV device needs to be protected from the high temperature of the thermal energy storage medium. The provision of a vacuum means that conduction and convection are reduced or eliminated and that radiative energy transfer is the primary means of transmission of energy from the thermal source to the PV device, which can be used to generate electrical power.

According to a second aspect of the present disclosure, there is provided a thermal energy storage facility including the thermal energy storage apparatus according to the first aspect of the present disclosure.

It is possible to provide a number of thermal energy storage apparatuses to provide the capability of storing and generating varying amounts of thermal energy and electrical energy respectively. The size and number of the thermal energy storage apparatuses can be adjusted to match the thermal and electrical energy requirements of the facility. For example, where there is a large source of thermal energy, which may be waste energy, a number of individual thermal energy storage apparatuses can be provided. Whilst a single large storage apparatus could be provided, in times of maintenance or breakdown, the capability to take in thermal energy and/or provide electrical energy would be nullified. As described in respect of the first aspect of the present disclosure, the energy storage facility may include one or more reservoirs for thermal energy that are able to accommodate higher temperatures and/or charging by different thermal energy sources. By providing such reservoirs, it is possible to transfer thermal energy from such reservoirs to a thermal storage apparatus configured to convert thermal energy to electrical energy as described in respect of the first aspect.

According to a third aspect of the present disclosure, there is provided an energy grid including the thermal storage apparatus of the first aspect, or energy storage facility according to the second aspect.

By integrating apparatuses and facilities of the present disclosure into an energy grid, which may be an electrical grid, it is possible to have a grid which is able to store electrical energy as thermal energy when electricity supply is greater than demand. Similarly, it is possible to store and utilise waste heat, which would otherwise simply be lost to the environment, to generate electricity. By providing such a combined energy storage and electricity generation capability, the overall efficiency of an electricity grid can be improved. In addition, the carbon intensity of an electricity grid can be reduced since energy created by intermittent sources, such as wind, can be stored for later conversion into electricity when electricity demand increases and/or supply drops.

According to a fourth aspect of the present disclosure, there is provided a method of improving the efficiency of an energy grid, the method including providing a thermal energy storage apparatus, energy storage facility or energy grid according to the first, second, or third aspects of the present disclosure, storing thermal energy within the thermal energy storage medium, and converting the stored thermal energy into electricity via illumination of the photovoltaic device.

The method may include storing thermal energy when there is an excess of electrical energy in the energy grid, when the price of a unit of electricity falls below a predetermined level, or when the carbon intensity of a unit of electricity falls below a predetermined level, and converting the stored thermal energy into electricity when there is a need for electrical energy in the energy grid, when the price of a unit of electricity rises above a predetermined level, or when the carbon intensity of a unit of electricity increases above a predetermined level.

According to a fifth aspect of the present disclosure, there is provided the use of a thermal energy storage apparatus, energy storage facility, or energy grid according to the first, second or third aspects or a method according to the fifth aspect of the present disclosure in a method of storing and releasing energy or in a thermal energy storage apparatus, energy storage facility, or energy grid.

Each of the aspects of the present disclosure may be combined with features of any other aspect of the present disclosure and all such combinations are explicitly considered and disclosed, except when features are functionally incompatible.

### BRIEF DESCRIPTION OF FIGURES

Embodiments of the invention will now be described, by way of example only, with reference to the accompanying schematic drawing in which corresponding reference symbols indicate corresponding parts, and in which:

FIGS. 1a to 1c depict an embodiment of the present disclosure utilising a single container;

FIGS. 2a and 2b depict an embodiment of the present disclosure which utilises two containers illuminating a photovoltaic device located therebetween;

FIG. 3a to 3c depict an individual fibre of a bidirectional waveguide, a bundle of waveguide fibres, and two bundles of waveguide fibres being confiured to illuminate both sides of a bifacial photovoltaic device;

FIGS. 4a to 4c depict embodiments in which the thermophotovoltaic device is unsupported, supported by an IR-transparent support, and supported by a bundle of optical waveguides;

FIG. 5 depicts an embodiment in which a second thermal source separated by a shutter is provided and configured to provide thermal energy to a thermal storage apparatus according to the present disclosure;

FIG. 6 depicts a plurality of waveguide fibres being brought together to concentrate the optical density of the fibres;

FIG. 7 depicts an embodiment of the present disclosure in which a plurality of lenses are configured to concentrate light onto a waveguide;

FIG. 8 depicts an embodiment of the present disclosure in which curved reflective surfaces are configured to collimate radiation from a radiative emitter located at the focal point of such reflective surface; and

FIG. 9 depicts an embodiment of the present disclosure in which a parabolic or elliptical reflective surface is configured to concentrate radiation from an array of emitters with collimating optical elements onto an array of photovoltaic devices positioned at the focal point of the reflective surface.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

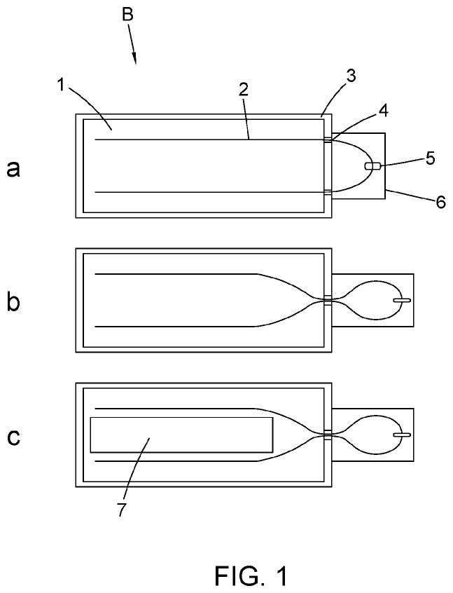

FIG. 1a is a schematic depiction of a thermal energy storage apparatus B according to the present disclosure. The apparatus B includes a thermal energy storage medium 1. The thermal energy storage medium 1 may be a mixed matrix of sensible and latent heat storage media, although it will be appreciated that in embodiments the thermal energy storage medium 1 may be either a sensible heat storage medium, or a latent heat storage medium. The apparatus included optical waveguide 2. In the depicted embodiment, there are two waveguides, but it will be appreciated that any number of waveguides may be used to allow thermal energy to be taken from and delivered to additional areas of the thermal storage medium 1. The thermal energy storage medium 1 is contained within an insulated container 3. The waveguides 2 pass through respective openings 4 in the insulated container 3 to an external photovoltaic device 5, which is contained within casing 6. The waveguides 2 are configured such that both faces of the bifacial photovoltaic device 5 are illuminated when in use. Any radiation which passes through the bifacial photovoltaic device 5 passes into the opposing waveguide 2 and is returned to the thermal energy storage medium 1, such that energy which is not converted into electricity in the first pass through the PV device 5 is not lost and can again be passed to the photovoltaic device 5.

FIG. 1b is similar to FIG. 1a, but instead of having two openings 4 in the insulated container 3, there is only a single opening 4. This reduces the number of openings in the insulated container 3, which can make for easier manufacture as well as improved thermal properties. In FIG. 1b, the angle of the waveguide 2 is selected such that it is greater than the minimum bend radius of the waveguide 2, which may be formed of fibres which can only be bent above a minimum bend radius.

FIG. 1c is similar to FIGS. 1a and 1b. In FIG. 1c, depicts an embodiment in which a thermal chamber 7 is provided. The thermal chamber 7 may comprise additional thermal energy storage medium, a combustion source, or an industrial heat source at a higher temperature than the thermal energy storage medium 1. In this way, the thermal chamber 7 is configured to provide thermal energy to the thermal energy storage medium 1. In other embodiments, the thermal energy storage medium 1 can be charged through other means, such as resistive heating or solar concentration.

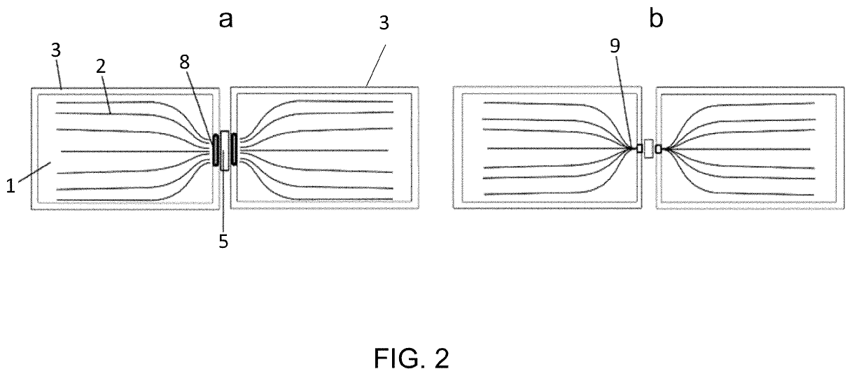

FIG. 2a depicts a configuration in which there are two insulated containers 3 that are arranged on either side of a bifacial photovoltaic device 5. In such a configuration, radiation from the thermal storage medium is guided by the bidirectional optical waveguides 2 to each face of the bifacial photovoltaic device 5. In this way, radiation which passes through the bifacial photovoltaic device 5 is guided back to the thermal energy storage medium 1 in the other insulated container 3. In the depicted embodiment, optional shutters 8, which may be mechanical shutters, are provided. The mechanical shutters 8 are configured to control the amount of radiation which is received by the bifacial photovoltaic device 5 via the bidirectional waveguides 2.

FIG. 2b is similar to FIG. 2a, although individual fibres comprising the optical waveguides 2 have been brought together at point 9 in order to concentrate the optical density onto the bifacial photovoltaic device 5, which allows for a smaller photovoltaic device to be used.

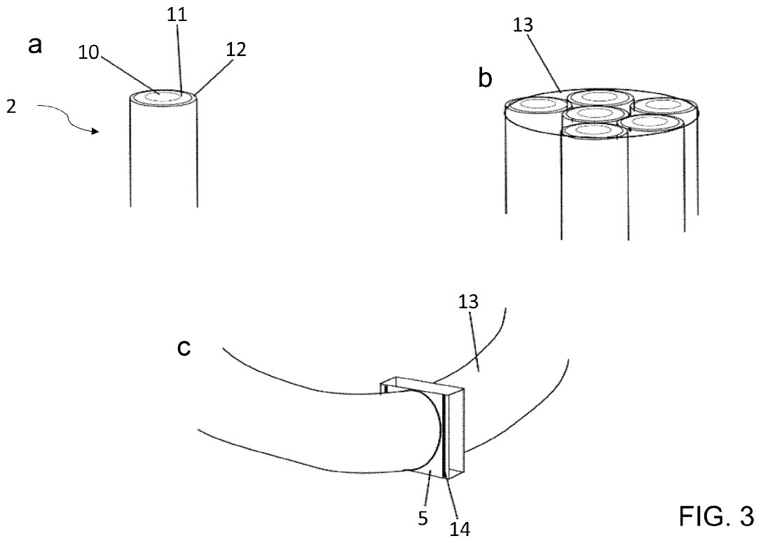

FIG. 3a depicts a cross-section through a single bidirectional waveguide 2. The bidirectional waveguide 2 comprises a core 10, cladding 11, and a coating 12. FIG. 3b depicts a bundle 13 of optical waveguides. It will be appreciated that the waveguides may be distributed as individual fibres throughout the thermal energy storage medium 1. The individual fibres may be bundled together to illuminate a photovoltaic device such that radiation from various areas of the thermal energy storage medium may be provided to the photovoltaic device. FIG. 3c depicts two bundles 13 of optical waveguides configured to guide radiation from a thermal energy storage medium to both faces of a bifacial photovoltaic device 5. The bundle 13 is configured such that it is within gridlines 14 of the metal contact electrodes of the bifacial photovoltaic device 5.

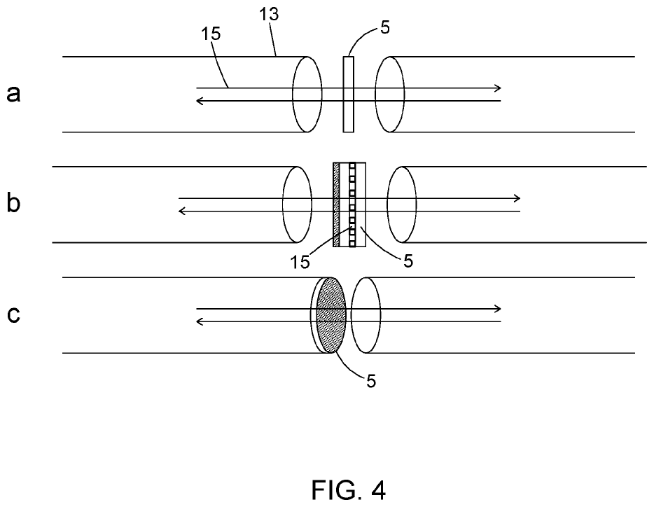

FIG. 4a depicts the light path 15 of a photon through a freestanding bidirectional photovoltaic device 5 via a bundle 13 of optical waveguides. It will be appreciated that a single waveguide fibre may be used rather than a bundle. As can be seen, light is provided from both sides of the photovoltaic device 5 and any light which is not absorbed by the photovoltaic device 5 is able to pass through the bundle 13 of optical waveguides on the other side of the photovoltaic device 5. Shorter wavelengths of light are converted into electricity while longer wavelengths are transmitted through the photovoltaic device 5 and returned to the thermal energy storage medium.

FIG. 4b is similar to FIG. 4a, but depicts a photovoltaic device 5 which is supported by an infra-red transparent support 15. FIG. 4c is similar to FIGS. 4a and 4b, although the photovoltaic device 5 is supported by the waveguide 2 or bundles of waveguides 13. In any embodiment, the photovoltaic device may be arranged with no or substantially no gap between the photovoltaic device and the waveguide, or a gap may exist for a coolant to be provided. Such coolant may flow over the faces of the photovoltaic device. In embodiments, there may be provided channels between the metal grid lines of the photovoltaic device through which coolant may be passed.

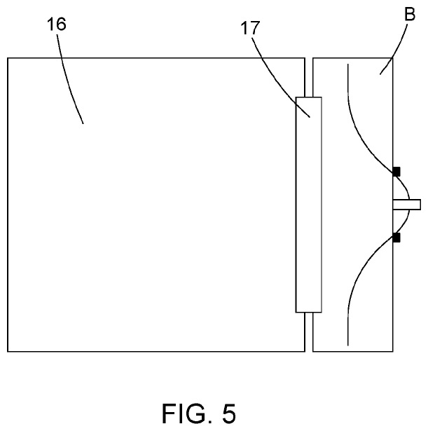

FIG. 5 depicts an embodiment of the present disclosure in which a second thermal source 16, which may be a second thermal energy storage apparatus according to the present disclosure which includes thermal energy storage medium at a higher temperature than a first thermal energy storage apparatus according to the present disclosure, separated from a first thermal energy storage apparatus according to the present disclosure. The second thermal source 16 may be a thermal battery at a higher temperature than a first thermal energy storage apparatus, a combustion source, a radioisotope source, an industrial waste heat source, or any other suitable heat source. The second thermal source 16 may be separated from the first thermal energy storage apparatus by one or more shutters 17. The one or more shutters 17 may be mechanical shutters. The shutters 17 may be opened to allow the transfer of thermal energy from the second thermal source 16 to the thermal energy storage apparatus B in order to recharge the thermal energy storage apparatus B. In the depicted embodiment, the thermal energy storage apparatus B includes a waveguide 2 which exits the insulated container, illuminates a photovoltaic device, and subsequently re-enters the insulated container.

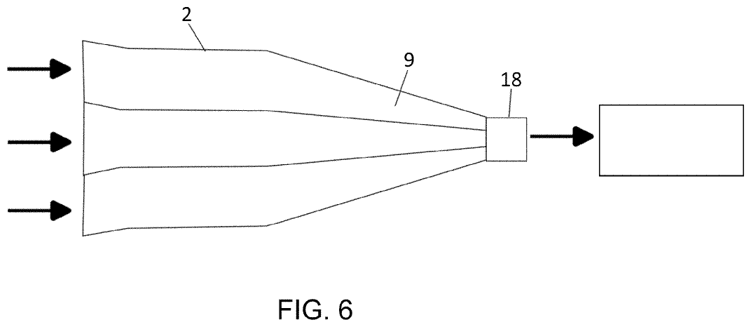

FIG. 6 depicts a plurality of waveguides 2 being brought together at point 9 to form single waveguide fibre 18. In this way, the energy being carried by the individual waveguides 2 can be concentrated into a single waveguide fibre 18. The waveguides 2 may be tapered to allow them to be brought together and formed into a single waveguide fibre 18. Since such waveguides are bidirectional, light which is returned via the single waveguide fibre 18 can be separated into the individual waveguide fibres 2 and returned to the thermal energy storage medium as required.

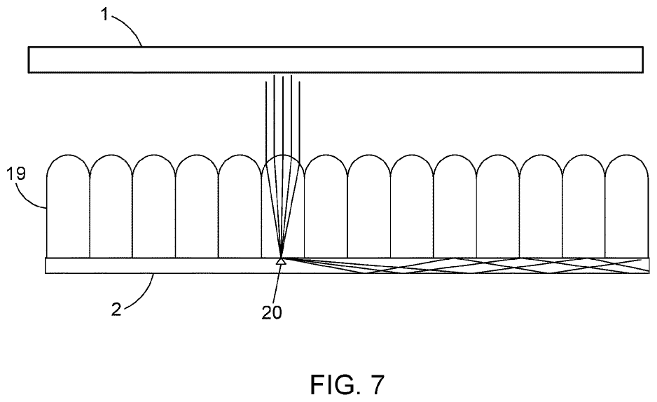

FIG. 7 depicts an embodiment of the present disclosure in which a plurality of lenses are configured to concentrate light onto a waveguide 2. The waveguide 2 may be in the form of a fibre or a slab. Blackbody emitter 1, which may be the thermal energy storage medium, emits radiation which is then focused by a lens 19. The lens 19 may be included in an array of lenses. A light coupling prism 20 may be provided to redirect light from a lens 20 to waveguide 2, and vice versa.

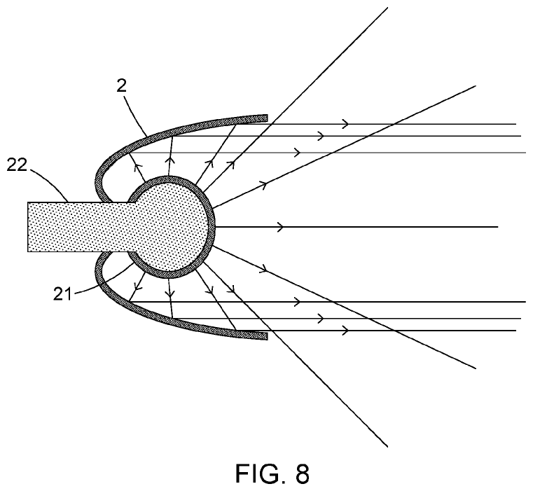

FIG. 8 depicts an embodiment of the present disclosure in which a waveguide in the form of a non-imaging optical element 2, such as a parabolic reflector dish/trough, collimates light from a point/rod emitter source 21 which is preferably made from high emissivity materials such as silicon carbide, while maintaining thermal contact with a heat source such as latent heat thermal storage through material structures 22 which may be the same material as the emitter or another material with high thermal conductivity such as Inconel or other steel. As can be seen, radiation is collimated by the waveguide 2 and is thereby guided towards a PV device for converting the thermal radiation energy into electrical energy.

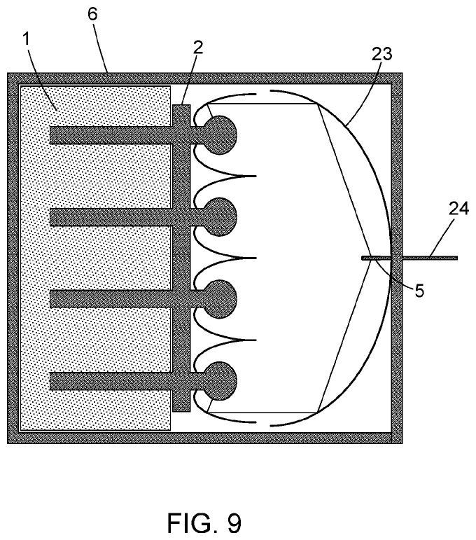

FIG. 9 depicts an an embodiment of the present disclosure in which an array of non-imaging optical elements 2, which may consist of an arbitrary number of repeat units of emitters and collimators such as those described in FIG. 8, face a larger non-imaging concentrator (waveguide) 23, such as a parabolic or ellipsoidal reflective dish or trough 23. An array of photovoltaic cells 5 is situated at the focal point of and mounted on a heatsink 24 through which coolant can flow and which may be fixed in place or retractable to remove the photovoltaic cells 5 from the light path. The waveguides 2 are in thermal contact with thermal energy storage medium 1. In use, thermal energy from the thermal energy storage medium 1 is passed via thermally conductive pathways, such as Inconel or steel, to one or more emitters. Optical waveguides guide radiation from the thermal energy storage medium to illuminate a PV device, which is configured to convert such thermal energy to electrical energy. The waveguides may rely upon, for example, reflection and/or refraction to guide the thermal energy radiation to the PV device.

In summary, the present disclosure provides a thermal battery which allows for more efficient conversion of thermal energy stored within a thermal energy storage medium into electricity by illuminating both sides of a photovoltaic device and providing waveguides which allow any light not converted into electricity to be returned to the thermal energy storage medium. This overcomes the issues with attempts to reflect light back through a photovoltaic device.

Aspects of the present disclosure are described in the following numbered clauses:
1. A thermal energy storage apparatus including a thermal energy storage medium, a bifacial photovoltaic device, and a bidirectional waveguide, wherein the bidirectional optical waveguide is configured to guide radiation from the thermal energy storage medium to both sides of the photovoltaic device and also to guide radiation which passes through the photovoltaic device back to the thermal storage medium.
2. The thermal energy storage apparatus according to claim 1, wherein the thermal energy storage medium includes a sensible heat storage medium, a latent heat storage medium, or a combination thereof.
3. The thermal energy storage apparatus according to claim 1 or claim 2, wherein the apparatus includes a heat storage medium directly adjacent the bidirectional optical waveguide.
4. The thermal energy storage apparatus according to any preceding claim, wherein the thermal energy storage medium is contained within an insulated container.
5. The thermal energy storage apparatus according to claim 4, wherein the photovoltaic device is located outside of the insulated container, optionally wherein the photovoltaic device is located within a housing.
6. The thermal energy storage apparatus according to any preceding claim, wherein the thermal energy storage apparatus further includes a heater configured to add thermal energy to the thermal energy storage medium, optionally wherein the heater is an electric heater, a heat exchanger in thermal connection with a heat source, another thermal energy storage apparatus at a higher temperature, a solar collector, a fuel device, a radioisotope heat source, or a burner.
7. The thermal energy storage apparatus according to any preceding claim, wherein the photovoltaic device is in thermal communication with a cooling apparatus, optionally wherein the cooling apparatus includes a flowing coolant configured to maintain the photovoltaic device within a predetermined temperature range.
8. The thermal energy storage apparatus according to any preceding claim, wherein the apparatus includes at least two storage chambers containing respective thermal energy storage media and bidirectional waveguides, optionally wherein the bidirectional waveguides are configured to provide radiation emitted from the thermal storage media to opposing sides of the photovoltaic device.
9. The thermal energy storage apparatus according to any preceding claim, wherein the apparatus further includes at least one shutter configured to control the amount of radiation reaching the photovoltaic device, optionally wherein the at least one shutter is a mechanical shutter.
10. The thermal energy storage apparatus according to any preceding claim, wherein the apparatus further includes a concentrating optical element configured to concentrate radiation on the photovoltaic device.
10b. The thermal energy storage apparatus according to any preceding claim, wherein the apparatus further includes a collimating optical element configured to collimate radiation towards the photovoltaic device or another optical element.
11. The thermal energy storage apparatus according to any preceding claim, wherein the bidirectional waveguide includes a plurality of individual waveguides, optionally wherein the width of the waveguides fits within gridlines of metal contact electrodes of the photovoltaic device.
11b. thermal energy storage apparatus according to any preceding claim, wherein the apparatus includes a plurality of non-imaging reflective optical elements to collimate and concentrate light onto the photovoltaic device.

12. The thermal energy storage apparatus according to any preceding claim, wherein the bidirectional waveguide is arranged to symmetrically illuminate both faces of the photovoltaic device.
13. The thermal energy storage apparatus according to any preceding claim, wherein the photovoltaic device is freestanding, supported by an infra-red transparent support, or supported by the waveguide.
14. The thermal energy storage apparatus according to any preceding claim, wherein the bidirectional waveguide comprise one or more of alumina, silica, and yttrium aluminium garnet (YAG).
15. The thermal energy storage apparatus according to any preceding claim, wherein the bidirectional waveguide includes thermoluminescent emitters configured to emit predetermined wavelengths of radiation, optionally wherein the thermoluminescent emitters are selected from transition metal oxides, rare earth oxides, or combinations thereof.
16. The thermal energy storage apparatus according to any preceding claim, wherein the thermal storage medium includes one or more of silicon, iron, aluminium, calcium, manganese, and magnesium, preferably wherein the thermal storage medium comprising such elements is a latent heat storage medium.
17. The thermal energy storage apparatus according to any preceding claim, wherein the photovoltaic device is separated from the thermal energy storage medium, optionally by a window or a vacuum.
18. An energy storage facility including the thermal energy storage apparatus according to any of claims 1 to 17.
19. An energy grid including the thermal storage apparatus or energy storage facility according to any of claims 1 to 18.
20. A method of improving the efficiency of an energy grid or energy storage facility, the method including providing a thermal energy storage apparatus, energy storage facility or energy grid according to any of claims 1 to 19, storing thermal energy within the thermal energy storage medium, and converting the stored thermal energy into electricity via illumination of the photovoltaic device.
21. The method according to claim 20, wherein the method includes storing thermal energy when there is an excess of electrical energy in the energy grid, when the price of a unit of electricity falls below a predetermined level, or when the carbon intensity of a unit of electricity falls below a predetermined level, and converting the stored thermal energy into electricity when there is a need for electrical energy in the energy grid, when the price of a unit of electricity rises above a predetermined level, or when the carbon intensity of a unit of electricity increases above a predetermined level.
22. The use of a thermal energy storage apparatus or energy storage facility or energy grid according to any of claims 1 to 19 or a method according to claim 20 or claim 21 in a method of storing and releasing energy or in a thermal energy storage apparatus, energy storage facility or energy grid.

1. A thermal energy storage apparatus including a thermal energy storage medium, a bifacial or monofacial photovoltaic device, and a bidirectional optical waveguide, wherein the bidirectional optical waveguide is configured to guide radiation from the thermal energy storage medium to one or both sides of the photovoltaic device and also to guide radiation which is reflected back or passes through the photovoltaic device back to the thermal storage medium.

2. The thermal energy storage apparatus according to claim 1, wherein the thermal energy storage medium includes a sensible heat storage medium, a latent heat storage medium, or a combination thereof.

3. The thermal energy storage apparatus according to claim 1, wherein the apparatus includes a heat storage medium directly adjacent the bidirectional optical waveguide.

4. The thermal energy storage apparatus according to claim 1, wherein the thermal energy storage medium is contained within an insulated container.

5. The thermal energy storage apparatus according to claim 4, wherein the photovoltaic device is located outside of the insulated container, optionally wherein the photovoltaic device is located within a housing.

6. The thermal energy storage apparatus according to claim 1, wherein the thermal energy storage apparatus further includes a heater configured to add thermal energy to the thermal energy storage medium, optionally wherein the heater is an electric heater, a heat exchanger in thermal connection with a heat source, another thermal energy storage apparatus at a higher temperature, a solar collector, a fuel device, a radioisotope heat source, or a burner.

7. The thermal energy storage apparatus according to claim 1, wherein the photovoltaic device is in thermal communication with a cooling apparatus, optionally wherein the cooling apparatus includes a flowing coolant configured to maintain the photovoltaic device within a predetermined temperature range.

8. The thermal energy storage apparatus according to claim 1, wherein the apparatus includes at least two storage chambers containing respective thermal energy storage media and bidirectional waveguides, optionally wherein the bidirectional waveguides are configured to provide radiation emitted from the thermal storage media to one or both faces of the photovoltaic device.

9. The thermal energy storage apparatus according to claim 1, wherein the apparatus further includes at least one shutter configured to control the amount of radiation reaching the photovoltaic device, optionally wherein the at least one shutter is a mechanical shutter.

10. The thermal energy storage apparatus according to claim 1, wherein the apparatus further includes a concentrating optical element configured to concentrate radiation on the photovoltaic device.

11. The thermal energy storage apparatus according to claim 1, wherein the apparatus includes a collimating optical element configured to collimate radiation towards the photovoltaic device or another optical element.

12. The thermal energy storage apparatus according to claim 1, wherein the bidirectional waveguide includes a plurality of individual waveguides, optionally wherein the width of the waveguides fits within gridlines of metal contact electrodes of the photovoltaic device.

13. The thermal energy storage apparatus according to claim 1, wherein the apparatus includes a plurality of non-imaging reflective optical elements to collimate and concentrate light onto the photovoltaic device.

14. The thermal energy storage apparatus according to claim 1, wherein the bidirectional waveguide is arranged to symmetrically illuminate both faces of the photovoltaic device.

15. The thermal energy storage apparatus according to claim 1, wherein the photovoltaic device is freestanding, supported by an infra-red transparent support, or supported by the waveguide.

16. The thermal energy storage apparatus according to claim 1, wherein the bidirectional waveguide comprise one or more of alumina, silica, and yttrium aluminium garnet (YAG).

17. The thermal energy storage apparatus according to claim 1, wherein the bidirectional waveguide includes thermoluminescent emitters configured to emit predetermined wavelengths of radiation, optionally wherein the thermoluminescent emitters are selected from transition metal oxides, rare earth oxides, or combinations thereof.

18. The thermal energy storage apparatus according to claim 1, wherein the thermal storage medium includes one or more of silicon, iron, aluminium, calcium, manganese, sodium, potassium, lithium and magnesium, preferably wherein the thermal storage medium comprising such elements is a latent heat storage medium.

19. The thermal energy storage apparatus according to claim 1, wherein the photovoltaic device is separated from the thermal energy storage medium, optionally by a window or a vacuum.

20. An energy storage facility including the thermal energy storage apparatus according to claim 1.

21. An energy grid including the thermal storage apparatus or energy storage facility according to claim 1.

22. A method of improving the efficiency of an energy grid or energy storage facility, the method including providing a thermal energy storage apparatus, energy storage facility or energy grid according to claim 1, storing thermal energy within the thermal energy storage medium, and converting the stored thermal energy into electricity via illumination of the photovoltaic device.

23. The method according to claim 22, wherein the method includes storing thermal energy when there is an excess of electrical energy in the energy grid, when the price of a unit of electricity falls below a predetermined level, or when the carbon intensity of a unit of electricity falls below a predetermined level, and converting the stored thermal energy into electricity when there is a need for electrical energy in the energy grid, when the price of a unit of electricity rises above a predetermined level, or when the carbon intensity of a unit of electricity increases above a predetermined level.

24. The use of a thermal energy storage apparatus or energy storage facility or energy grid according to claim 1 in a method of storing and releasing energy or in a thermal energy storage apparatus, energy storage facility or energy grid.
